(19) United States
(12) Patent Application Publication
(10) Pub. No.: US 2014/0320142 A1
(43) Pub. Date: Oct. 30, 2014

(54) METHOD AND SYSTEM FOR MEASURING ELECTRIC CURRENT

(71) Applicant: RENAULT s.a.s., Boulogne Billancourt (FR)

(72) Inventor: Pietro Dolcini, Paris (FR)

(73) Assignee: RENAULT s.a.s., Boulogne Billancourt (FR)

(21) Appl. No.: 14/357,362

(22) PCT Filed: Oct. 30, 2012
(86) PCT No.: PCT/EP2012/071469

§ 371 Date: May 9, 2014

(30) Foreign Application Priority Data
Nov. 10, 2011 (FR) 1160260

(51) Int. Cl. G01R 35/00; G01R 31/36

(52) U.S. Cl. CPC G01R 35/005; G01R 31/361
USPC 324/426; 324/251

(57) ABSTRACT

A system for measuring electric current supplied by an electric battery, for example a battery in a motor vehicle, including: a Hall effect current sensor; a device for compensating for measurement errors made by the sensor, including a mechanism applying an operation close to the inverse of an operator characterizing magnetic hysteresis of the sensor to the measured current.

The invention relates to the technical field of electric current sensors and in particular to that of current sensors using the Hall effect. The invention is applicable, notably, to the measurement of the current of an electric battery, for example a battery fitted to a motor vehicle.

The use of Hall effect current sensors for measuring electric current is known from the prior art. These sensors are susceptible to various types of measurement errors, namely offset errors, gain and linearity errors, and errors due to magnetic hysteresis.

Patent application EP 0877232 discloses a method of compensating for offset errors by simple comparison of the measurements of the Hall effect sensor with the current measurement made for a known current value.

Compensation for gain and linearity errors by calibration or mapping is known from the prior art.

A method of compensation for errors due to the magnetic hysteresis of the sensors is also known. However, this method requires an active current loop. Therefore sensors using this method, called closed loop sensors, have a higher power consumption and are more expensive than open-loop sensors.

Additionally, a hysteresis compensation method, in which jumps in value are suppressed during dynamic loading of a force sensor, is known from patent application EP 077997 1. Furthermore, a hysteresis compensation method providing compensation for magnetic fields which are external to the sensor and measurable is known from patent application US2007038401.

However, these two patent applications are not concerned with magnetic hysteresis. Consequently there is a need to improve the present method of compensation for errors due to magnetic hysteresis in Hall effect current sensors.

According to the invention, a precise current measurement system, which does not increase the power consumption of the sensor or its cost relative to a conventional Hall effect sensor, is proposed.

Additionally, according to the invention, a measurement system allowing precise compensation for the magnetic hysteresis with a reasonable amount of calculation is proposed.

According to the invention, a simple compensation method is proposed, providing real time processing of the current measurement which is easily implemented.

Thus the invention proposes a system for measuring electric current supplied by an electric battery, notably a battery fitted to a motor vehicle, comprising:

a Hall effect current sensor;

a device for compensating for the measurement errors of the sensor, comprising means for applying to the measured current an operation approximating the inverse of an operator characterizing the magnetic hysteresis of the sensor.

It is thus possible to compensate for the hysteresis of a Hall effect sensor in an open loop. This makes it possible to maintain a power consumption and cost similar to those of a conventional Hall effect sensor with fewer measurement errors due to hysteresis.

According to one characteristic, the error compensation system further comprises a subtractor to deduct the offset error of the Hall effect current sensor from the measured current, followed by a multiplier to compensate for the gain error of the Hall effect current sensor.

It is thus possible to combine the hysteresis compensation with compensation for the offset and gain errors.

According to one embodiment, the operator is a Play operator, and the means of applying an operation to the measured current comprise:

a means of applying a delay;

a subtractor for determining the difference between the delayed measured intensity and the measured intensity;

means for extracting a positive or negative sign from the difference between the delayed measured current intensity and the measured current intensity;

means for assigning the extracted sign to a constant depending on the width of the hysteresis cycle;

a subtractor for subtracting the constant to which the sign is assigned from the measured current intensity.

Thus the operation for approximating the inverse of the Play operator is very simple. This is particularly useful because it allows real time correction of the measured current intensity. Thus, for example in the case of an application to energy reserve measurement, the correct current intensity can be takers into account for a continuous display of the energy reserve.

The invention also proposes a method for measuring electric current supplied by an electric battery, notably a battery fitted to a motor vehicle, comprising:

a step of measuring the current by means of a Hall effect sensor;

a step of compensating for the measurement errors of the sensor, comprising the application to the measured current of an operation approximating the inverse of an operator characterizing the magnetic hysteresis of the sensor.

According to one characteristic, the error compensation step further comprises a step of correction of the offset and gain errors of the Hall effect sensor.

According to another characteristic, the operator is a Play operator according to which the hysteresis cycle of the real current intensity expressed as a function of the measured intensity comprises two parallel straight lines and the method comprises a preliminary step of characterization of the Hall effect sensor, comprising:

calculation of the sign of the derivative of the measured current intensity;

selection of one of the two parallel straight lines as a function of the sign of the derivative; and

determination of the actual current intensity corresponding to the measured current intensity on the selected straight line.

Thus the characterization of the Hall effect sensor can be carried out in a simple manner.

According to one embodiment, the operator is a Play operator, and said operation comprises:

the application of a delay to the measured current intensity;

determination of the difference between the delayed measured current intensity and the measured current intensity;

extraction of a positive or negative sign from the difference between the delayed measured current intensity and the measured current intensity;

assignment of the extracted sign to a constant depending on the width of the hysteresis cycle; and

subtraction of the constant to which the sign is assigned from the measured current intensity.

According to another aspect, it is proposed that the system defined above be used to determine an estimate of the energy reserve of an electrically propelled vehicle fitted with an electric battery.

In this way, the precision of the estimation of the energy reserve of a vehicle of this type can be improved.

In order to determine this estimate, the system is connected, for example, to integrators. This use is advantageous because, in the particular case of an electrically propelled vehicle, the current profile is not symmetrical (the current mainly flows from the battery toward the electric motor) and the errors due to magnetic hysteresis are particularly harmful for the measurement of the energy reserve, for example .This is not necessarily the case for hybrid vehicles or those propelled by heat engines, in which the current profile is symmetrical (the current flows to and from the battery during operation), making it possible to compensate for errors due to magnetic hysteresis for the energy reserve measurement.

Other characteristics and advantages of the invention will become apparent from the detailed description of an application and embodiment, which is not limiting in any way, and the appended drawings, in which:

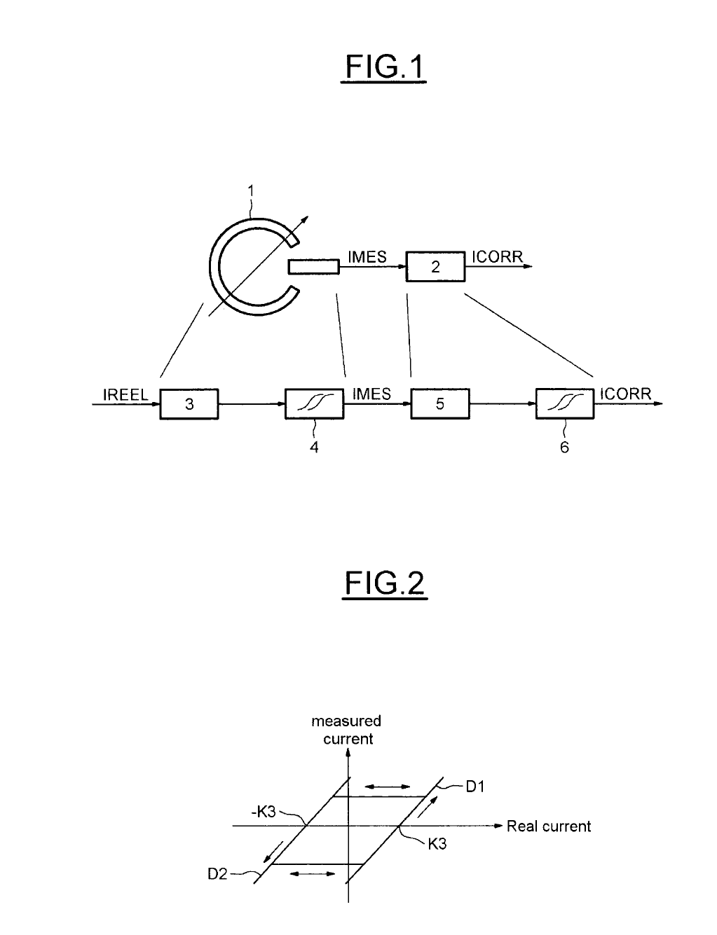

FIG. 1 shows schematically an electric current measurement system using a Hall effect current sensor and provided with a compensation device;

FIG. 2 shows schematically the operating principle of a Play operator;

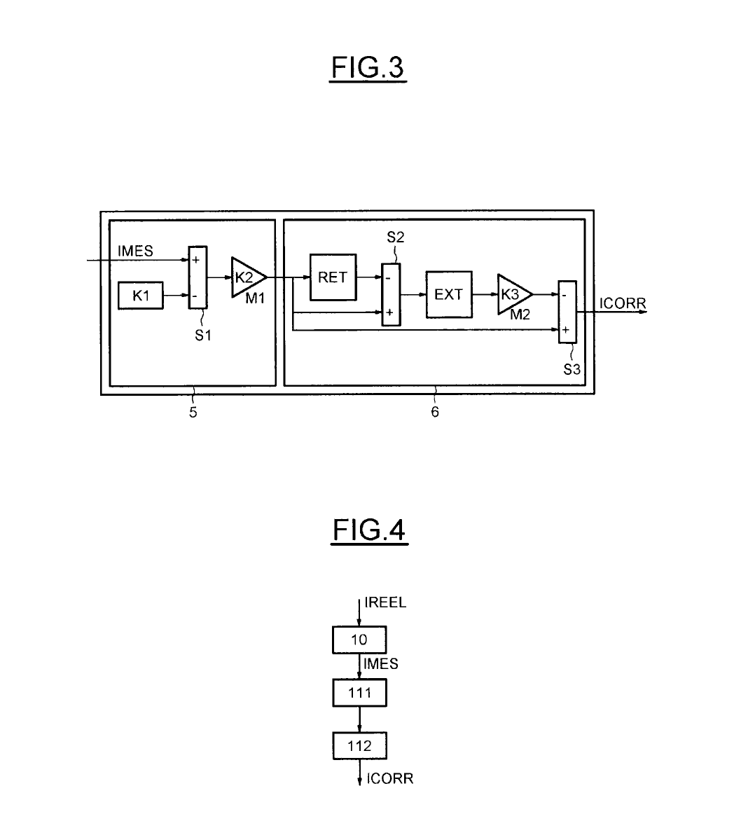

FIG. 3 shows a transformation means according to an embodiment of the invention; and

FIG. 4 shows a transformation means according to another embodiment of the invention.

FIG. 1 shows a Hall effect sensor 1 represented by a ring through which the real current intensity IREEL passes. This sensor is connected to the output of a battery and measures a measured current intensity IMES based on the real current intensity IREEL.

The IMES measurement exhibits measurement errors, namely offset and gain errors and errors due to the magnetic hysteresis of the Hall effect sensor. The linearity errors are generally already compensated for by the Hall effect sensor available on the market.

The system is provided with a measurement error compensation device 2 connected to the output of the Hall effect sensor, which compensates for the measurement errors. At the output of the device 2, the corrected current intensity ICORR then has fewer measurement errors than the current intensity IMES.

The sensor 1 can be represented schematically as a block 3 followed by a block 4, representing the addition of the measurement errors of the sensor 1. Block 3 corresponds to the offset and gain errors. Block 4 corresponds to the errors due to magnetic hysteresis.

The measurement error compensation device 2 can be represented schematically as a block 5 followed by a block 6, representing compensation for the measurement errors of the sensor 1. Block 5 corresponds to the corrections of the offset and gain errors, and the block 6 corresponds to the corrections of the errors due to magnetic hysteresis.

In an exemplary embodiment, block 5 adds to each measurement IMES a first constant K1 and multiplies the result by a second constant K2.

The constant K1 is determined, for example, by finding the mean of a plurality of values of measured current IMES for a monitored real current intensity IREEL_cont having a zero value. The constant K1 therefore corresponds to the offset error of the Hall effect current sensor.

The constant K2 is determined, for example, by finding the mean of the ratio between the monitored values of real current intensity IREELcont and a plurality of corresponding measured values IMES. The constant K2 therefore corresponds to the inverse of the gain error of the sensor.

Block 6 comprises means for applying to the measured current an operation approximating the inverse of an operator characterizing the magnetic hysteresis of the sensor 1. In other words, after a preliminary characterization of the hysteresis by an operator, for example a Play operator or a Preisach operator, block 6 will apply an operation approximating the inverse of this operator to the current intensity at the output of block 5.

In the case of a Preisach operator, its approximate inversion is described in “Approximate Inversion of the Preisach Hysteresis Operator With Application to Control of Smart Actuators”, IEEE Transactions on Automatic Control, Vol. 50, No. 6, June 2005. In all cases, the inversion of the Preisach operator is very resource-intensive, since it requires a variable for each sampling interval. By way of example, in the case of a current amplitude of +1-6 A with a resolution of 0.5 mA, at least 1200 variables are required. Not only is a large number of variables used, but the inversion is also performed by an iterative calculation at each sampling interval.

According to an advantageous embodiment of the invention, a Play operator, such as that shown in FIG. 2, which is very simple to invert, is chosen for the characterization of the magnetic hysteresis of the Hall effect sensor.

The horizontal axis represents the real current IREEL, and the vertical axis represents the measured current IMES. Depending on whether the real current IREEL is increasing or decreasing, the value of the measured current is represented, respectively, by the ascending straight line D1 or the descending straight line D2. The slope of each of the straight lines D1 and D2 is 1.

In the case of a hysteresis represented by the Play operator, three values enabling the measurement errors of the Hall effect sensor to be characterized are determined, namely:

the value K1 corresponding to the offset error;

the value K2 corresponding to the inverse of the gain error of the sensor; and

the value K3 corresponding to the width of the hysteresis cycle.

These values are determined by a preliminary characterization and/or calibration of the Hall effect sensor 1.

An example of characterization of a Hall effect sensor in the case of a Play operator such as that shown in FIG. 2 comprises:

calculation of the sign of the derivative of the measured current intensity IMES;

selection of one of the two parallel straight lines D1 and D2 as a function of the sign of the derivative. More precisely, the straight line D1 is selected if the derivative is positive and the straight line D2 is selected if the derivative is negative; and

determination of the real current intensity IREEL corresponding to the measured current intensity on the selected straight line.

During this bench characterization, it is found that the width of the hysteresis cycle K3 is very small relative to the amplitude of the measurements from −400 to 200 A. This validates the approximation of the hysteresis by two parallel straight lines of the Play operator.

FIG. 3 shows a specific embodiment of blocks 5 and 6 of the device for compensating for the measurement errors of the sensor 1.

Block 5 comprises a subtractor S1 for deducting the offset error of the Hall effect current sensor K1 from the measured current IMES, followed by a multiplier M1 for compensating for the gain error of the Hall effect current sensor 1 by multiplying the result of the subtraction by the inverse of the gain of the sensor, K2.

Block 6 comprises means for determining the sign of the derivative, comprising means for applying a delay RET and a subtractor S2 for determining the difference between the delayed current intensity and the non-delayed current intensity.

Block 6 also comprises means EXT for extracting the positive or negative sign of the derivative and assignment means, for example a multiplier M2, for assigning the extracted sign to the constant K3 corresponding to the width of the hysteresis cycle.

Finally, block 6 comprises a subtractor S3 for subtracting from the measured current intensity IMES the constant K3 to which the sign is assigned: +/−K3.

In other words, the corrected current intensity is: ICORR=(IMES−K1)·K2−sign(IMES(t)−IMES(t−1))·K3

Thus an inversion of an operator characterizing the hysteresis is performed in a simple manner, and it is then possible to compensate for the hysteresis on the measured current intensity IMES in real time; that is to say, the compensation is carried out on each successive current measurement before the next measurement of the sensor 1.

FIG. 4 shows the steps of a method for measuring the current intensity according to the invention, using the Hall effect sensor 1.

In a first step 10, the current IREEL is measured by the sensor 1. The measurement made is IMES. Then, in a step 111, the offset and gain errors in the measured current IMES relative to the real current IREEL are compensated for. This step is performed by block 5. Finally, in a step 112, the errors in the measured current IMES due to magnetic hysteresis are compensated for. This step is performed by block 6.

After the two compensation steps 111 and 112, the measured current IMES is corrected and has the value ICORR.

1-8. (canceled)

9. A system for measuring electric current, comprising:
a Hall effect current sensor; and
a device for compensating for measurement errors of the sensor, comprising means for applying to measured current an operation approximating the inverse of an operator characterizing magnetic hysteresis of the sensor.

10. The system as claimed in claim 9, wherein the error compensation system further comprises a subtractor to deduct an offset error of the Hall effect current sensor from the measured current, followed by a multiplier to compensate for a gain error of the Hall effect current sensor.

11. The system as claimed in claim 9, wherein the operator is a Play operator and wherein the means for applying an operation to the measured current comprises:
a means of applying a delay;
a first subtractor for determining a difference between a delayed measured current intensity and the measured current intensity;
means for extracting a positive or negative sign from the difference between the delayed measured current intensity and the measured current intensity;
means for assigning the extracted sign to a constant depending on a width of the hysteresis cycle; and
a second subtractor for subtracting the constant to which the sign is assigned from the measured current intensity.

12. A method for measuring an electric current, comprising:
measuring a current by a Hall effect sensor; and
compensating for measurement errors of the sensor, comprising application to the measured current of an operation approximating an inverse of an operator characterizing magnetic hysteresis of the sensor.

13. The method as claimed in claim 12, wherein the error compensation further comprises correction of offset and gain errors of the Hall effect sensor.

14. The method as claimed in claim 12, wherein the operator is a Play operator according to which a hysteresis cycle of real current intensity expressed as a function of the measured current intensity comprises two parallel straight lines, the method further comprising a preliminary characterization of the Hall effect sensor, comprising:
calculation of a sign of a derivative of the measured current intensity;
selection of one of two parallel straight lines as a function of the sign of the derivative; and
determination of the real current intensity corresponding to the measured current intensity on the selected straight line.

15. The method as claimed in claim 12, wherein the operator is a Play operator and the operation comprises:
application of a delay to the measured current intensity;
determination of a difference between the delayed measured current intensity and the measured current intensity;
extraction of a positive or negative sign from the difference between the delayed measured current intensity and the measured current intensity;
assignment of the extracted sign to a constant depending on a width of the hysteresis cycle; and
subtraction of the constant to which the sign is assigned from the measured current intensity.

16. Use of a system as claimed in claim 9, for determining an estimate of an energy reserve of an electrically propelled vehicle fitted with an electric battery.
